(19) United States
(12) Patent Application Publication
(10) Pub. No.: US 2024/0256937 A1
(43) Pub. Date: Aug. 1, 2024

(54) Apparatus and Method of Generating Multidimensional Quantum States Through Space Division Multiplexing of Single Photon

(71) Applicant: Pusan National University Industry-University Cooperation Foundation, Busan (KR)

(72) Inventors: Han-Seb MOON, Busan (KR); Changhoon BAEK, Busan (KR)

(21) Appl. No.: 18/501,030

(22) Filed: Nov. 3, 2023

(30) Foreign Application Priority Data
Nov. 8, 2022 (KR) 10-2022-0147883
May 10, 2023 (KR) 10-2023-0060238

(51) Int. Cl. G06N 10/40; G02F 1/01; H03L 7/26

(52) U.S. Cl. CPC G06N 10/40; G02F 1/0121; H03L 7/26; G02F 2203/12

(57) ABSTRACT

The present disclosure relates to an apparatus and method of generating a multidimensional quantum state through space division multiplexing of a single photon. The multidimensional quantum state generation apparatus includes a photon generator configured to generate a single photon, and a multidimensional quantum state generator configured to generate a multidimensional quantum state by space division multiplexing a state of the single photon through phase modulation of a spatial light modulator (SLM).

### CROSS-REFERENCE TO RELATED APPLICATION

This application claims the benefit of Korean Patent Application No. 10-2022-0147883 filed on Nov. 8, 2022, and Korean Patent Application No. 10-2022-0060238 filed on May 10, 2023 in the Korean Intellectual Property Office, the entire disclosures of which are incorporated herein by reference for all purposes.

### BACKGROUND

### 1. Field of the Invention

The following embodiments relate to a technique to improve quantum information processing.

### 2. Description of the Related Art

Quantum computing is a new computing method using a quantum mechanical phenomenon such as superimposition of two quantum states or entanglement of quantum states included in an individual and remote entities. Unlike digital computing that stores and manipulates information using “bits” configured to make a bistable state (e.g., “0” and “1”), the quantum computing system aims to manipulate information using “quantum bits (qubits)” configured to superimpose quantum states (e.g., a|0>+b|1>). Quantum states of qubits may be entangled with each other. That is, a measurement result of one qubit may be correlated with measurement results of other qubits.

It may be identified that a qubit is efficient since the qubit may transmit more information than an existing bit.

If it is able to generate a multidimensional quantum state by a single photon, more information may be encoded than a qubit.

### SUMMARY

The present disclosure provides an apparatus and method of generating a multidimensional quantum state through space division multiplexing of a single photon.

According to an aspect, there is provided a multidimensional quantum state generation apparatus including a photon generator configured to generate a single photon, and a multidimensional quantum state generator configured to generate a multidimensional quantum state by space division multiplexing a state of the single photon through phase modulation of a spatial light modulator (SLM).

The single photon includes a heralded single photon.

The multidimensional quantum state generator is configured to generate a two-dimensional quantum state by space dividing multiplexing the state of the single photon into a left side and a right side through phase modulation of the SLM.

The multidimensional quantum state generator is configured to generate a two-dimensional quantum state by space dividing multiplexing the state of the single photon into a top side and a bottom side through phase modulation of the SLM.

The multidimensional quantum state generator is configured to generate a four-dimensional quantum state by space dividing multiplexing the state of the single photon into top, bottom, left, and right quadrants through phase modulation of the SLM.

The multidimensional quantum state generator is configured to generate a two-dimensional quantum state by space division multiplexing by dividing the state of the single photon into top, bottom, left, and right quadrants through phase modulation of the SLM, allocate a same phase to top-left and bottom-right of the divided quadrants, and allocate a same phase to top-right and bottom-left of the divided quadrants.

The multidimensional quantum state is dividable into multidimensions up to a range supported by a resolution of the SLM.

The photon generator includes an atomic vapor cell containing a rubidium (⁸⁷Rb) atom, and a processor configured to move a coupling laser and a pump laser in opposite directions to each other relative to the atomic vapor cell, generate a pair of signal and idler photons in the atomic vapor cell, and output a signal photon as the single photon.

The coupling laser includes a 776 nm laser of horizontal polarization, the pump laser includes a 780 nm laser of vertical polarization, and the coupling laser and the pump laser simultaneously move toward the atomic vapor cell in opposite directions to each other from respective positions spaced apart from the atomic vapor cell by a same distance.

The processor is configured to generate the photon pair of which the signal and the idler are in a perpendicular polarization relationship that is horizontal polarization and vertical polarization or vertical polarization and horizontal polarization by the coupling laser of horizontal polarization and the pump laser of vertical polarization.

The coupling laser and the pump laser fix a laser frequency at +1 GHz outside a Doppler broadening region to reduce an irrelevant photon pair generated by photon resonance.

The atomic vapor cell includes a glass-type cell that maintains gas of the rubidium (⁸⁷Rb) atom warm.

According to an aspect, there is provided a method of generating a multidimensional quantum state including generating a single photon, and generating a multidimensional quantum state by space division multiplexing a state of the single photon through phase modulation of an SLM.

The generating of the multidimensional quantum state includes generating a two-dimensional quantum state by space dividing multiplexing the state of the single photon into a left side and a right side through phase modulation of the SLM.

The generating of the multidimensional quantum state includes generating a two-dimensional quantum state by space dividing multiplexing the state of the single photon into a top side and a bottom side through phase modulation of the SLM.

The generating of the multidimensional quantum state includes generating a four-dimensional quantum state by space dividing multiplexing the state of the single photon into top, bottom, left, and right quadrants through phase modulation of the SLM.

The generating of the multidimensional quantum state includes generating a two-dimensional quantum state by space division multiplexing by dividing the state of the single photon into top, bottom, left, and right quadrants through phase modulation of the SLM, allocating a same phase to top-left and bottom-right of the divided quadrants, and allocating a same phase to top-right and bottom-left of the divided quadrants.

The generating of the single photon includes providing an atomic vapor cell containing a rubidium (⁸⁷Rb) atom, and moving a coupling laser and a pump laser in opposite directions to each other relative to the atomic vapor cell, generating a pair of signal and idler photons in the atomic vapor cell, and outputting a signal photon as the single photon.

The providing of the atomic vapor cell includes providing a glass-type cell that maintains gas of the rubidium (⁸⁷Rb) atom warm.

The present disclosure relates to an apparatus and method of generating a multidimensional quantum state through space division multiplexing of a single photon. Arbitrary superimposition of a photon quark may be easily controlled by adjusting a phase of each section using a spatial light modulator (SLM), and a large information capacity per photon may be provided for a quantum computer and quantum communication by providing a multidimensional photonic quantum state.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram illustrating a configuration of an apparatus for generating a multidimensional quantum state according to one embodiment of the present disclosure;

FIG. 2A is a diagram illustrating an energy level diagram of 5S_{1/2}-5P_{3/2}-5D_{5/2} transition of an ⁸⁷Rb atom according to one embodiment of the present disclosure;

FIG. 2B is a diagram illustrating an example of implementing a multidimensional quantum state of a heralded single photon generated by a warm ⁸⁷Rb atom of a cascade type according to one embodiment of the present disclosure;

FIG. 3A is a diagram illustrating an output planar image obtained by an electron-multiplying charged coupled device (EMCCD) camera before and after optimization of the spatial light modulator (SLM) of FIG. 2B;

FIG. 3B is a diagram illustrating a normalized cross-correlation function between a signal photon detected by SPD1 of FIG. 2B and an idler photon detected by SPD2 (a trigger detector) of FIG. 2B;

FIG. 4A is a diagram illustrating an example of dividing the surface of an SLM of a multidimensional quantum state generation apparatus into four segments according to one embodiment of the present disclosure;

FIG. 4B is a diagram illustrating a normalized number of a single photon when a relative phase changes to 234 stages from 0 to 2p in the multidimensional quantum state generation apparatus according to one embodiment of the present disclosure;

FIG. 5A is a diagram illustrating quantum interference of a single photon qubit when the surface of an SLM is divided into top and bottom according to one embodiment of the present disclosure;

FIG. 5B is a diagram illustrating quantum interference of a single photon qubit when the surface of an SLM is diagonally divided according to one embodiment of the present disclosure;

FIG. 6A is a diagram illustrating an example of measuring interference in a four-dimensional (4D) space quantum state in the case of φ₁=0, φ₂=φ, φ₃=2φ, φ₄=3φ in a multidimensional quantum state generation apparatus according to one embodiment of the present disclosure;

FIG. 6B is a diagram illustrating an example of measuring interference in a four-dimensional (4D) space quantum state in the case of φ₁=0, φ₂=3φ, φ₃=6φ, φ₄=9φ in a multidimensional quantum state generation apparatus according to one embodiment of the present disclosure;

FIG. 7A is a diagram illustrating an example of dividing the surface of an SLM of a multidimensional quantum state generation apparatus into three segments according to one embodiment of the present disclosure;

FIG. 7B is a diagram illustrating an example of measuring interference of a 3D space quantum state when the surface of an SLM of a multidimensional quantum state generation apparatus is divided into three segments according to one embodiment of the present disclosure;

FIG. 8A is a diagram illustrating an example of dividing the surface of an SLM of a multidimensional quantum state generation apparatus into five segments according to one embodiment of the present disclosure;

FIG. 8B is a diagram illustrating an example of measuring interference of a 3D space quantum state when the surface of an SLM of a multidimensional quantum state generation apparatus is divided into five segments according to one embodiment of the present disclosure;

FIG. 9A illustrates an example of dividing one state of a single photon into three quantum states |1 [symbol] , |2 [symbol] , |3 [symbol] by dividing three segments of an SLM by the same ratio;

FIG. 9B is a diagram illustrating an example of making one state of a single photon one quantum state |1 [symbol] by dividing three segments of the SLM mainly based on a first segment;

FIG. 9C is a diagram illustrating an example of dividing one state of a single photon into two diagonally divided quantum states |2 [symbol] , |3 [symbol] by dividing three segments of the SLM mainly based on second and third segments;

FIG. 9D is a diagram illustrating an example of dividing one state of a single photon into two laterally divided quantum states |1 [symbol] , |2 [symbol] by dividing three segments of the SLM mainly based on the first and second segments; and

FIG. 10 is a flowchart illustrating a process of generating a multidimensional quantum state according to one embodiment of the present disclosure.

### DETAILED DESCRIPTION

Hereinafter, example embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular example embodiments only and is not to be limiting of the example embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like constituent elements and a repeated description related thereto will be omitted. In the description of embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The same name may be used to describe an element included in the example embodiments described above and an element having a common function. Unless otherwise mentioned, the descriptions on the example embodiments may be applicable to the following example embodiments and thus, duplicated descriptions will be omitted for conciseness.

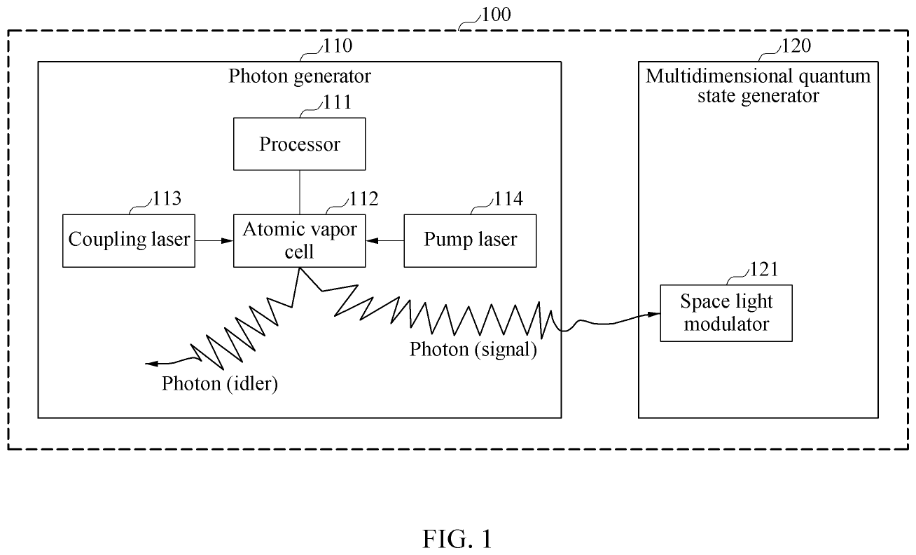

Hereinafter, an apparatus and method of generating a multidimensional quantum state through space division multiplexing of a single photon are described with reference to FIGS. 1 to 10, according to one embodiment of the present disclosure.

FIG. 1 is a diagram illustrating a configuration of an apparatus for generating a multidimensional quantum state according to one embodiment of the present disclosure.

Referring to FIG. 1, an apparatus for generating a multidimensional quantum state 100 (hereinafter, also referred to as a multidimensional quantum state generation apparatus) may include a photon generator 110 and a multidimensional quantum state generator 120.

The photon generator 110 may generate a single photon. In this case, the single photon may be a heralded single photon.

More specifically, the photon generator 110 may include an atomic vapor cell 112, a coupling laser 113, a pump laser 114, and a processor 111.

The atomic vapor cell 112 may be a cell containing a rubidium (⁸⁷Rb) atom. In this case, the atomic vapor cell 112 may be a glass-type cell that maintains the gas of rubidium (⁸⁷Rb) atom warm. By using the warm atomic medium, the atomic vapor cell 110 of the present disclosure may generate a more stable photon pair by a simple apparatus compared to a conventional atomic medium.

The atomic vapor cell 112 may be formed of a glass tube filled with rubidium 87 isotopes in a vacuum state. The rubidium atoms in the atomic vapor cell 113 may be maneuvered (captured, pumped, and the like) by the coupling laser 113 and the pump laser 114, which are described below, and may generate two photons. In this case, the two generated photons (a photon pair) may be in a quantum entanglement state.

The processor 111 may move the coupling laser 113 and the pump laser 114 from opposite directions to each other relative to the atomic vapor cell 112, may generate a photon pair of a signal photon and an idler photon by the atomic vapor cell 112, and may output the signal photon as a single photon. In this case, the coupling laser 110 may be a 776 nm laser of horizontal polarization and the pump laser 114 may be a 780 nm laser of vertical polarization. The horizontal polarization may refer to polarization in a horizontal direction based on a traveling direction of a laser and the vertical polarization may refer to polarization in a vertical direction based on a traveling direction of a laser. In addition, the coupling laser 113 and the pump laser 114 may simultaneously move toward the atomic vapor cell in opposite directions to each other at positions apart from the atomic vapor cell by the same distance.

The processor 111 may generate a photon pair of which a signal and an idler have a perpendicular polarization relationship that is horizontal polarization and vertical polarization or vertical polarization and horizontal polarization by the coupling laser 113 of horizontal polarization and the pump laser 114 of vertical polarization. The coupling laser 113 and the pump laser 114 may fix a laser frequency at +1 GHz outside of a Doppler broadening region to reduce an irrelevant photon pair generated by photon resonance.

The multidimensional quantum state generator 120 may generate a multidimensional quantum state by space division multiplexing a state of a single photon output by the photon generator 110 through phase modulation of a spatial light modulator (SLM) 121.

The multidimensional quantum state generator 120 may generate a two-dimensional quantum state by space division multiplexing a single photon state into left and right sides through phase modulation of the SLM 121.

The multidimensional quantum state generator 120 may generate a two-dimensional quantum state by space division multiplexing a single photon state into top and bottom sides through phase modulation of the SLM 121.

The multidimensional quantum state generator 120 may generate a four-dimensional quantum state by space division multiplexing a single photon state into the top, bottom, left, and right sides through phase modulation of the SLM 121.

The multidimensional quantum state generator 120 may generate a two-dimensional quantum state by space division multiplexing by dividing a single photon state into top, bottom, left, and right quadrants through phase modulation of the SLM 121, allocating the same phase to top-left and bottom-right of the divided quadrants, and allocating the same phase to top-right and bottom-left of the divided quadrants.

The multidimensional quantum state generator 120 may divide into multiple dimensions up to a range supported by the resolution of the SLM 121. In the present disclosure, division may be available into approximately 200 dimensions.

In the present disclosure, a description is provided based on a heralded single photon generated by Doppler broadening cascade type atom ensemble based on 5S_{1/2}-5P_{3/2}-5D_{5/2} transition of an ⁸⁷Rb atom.

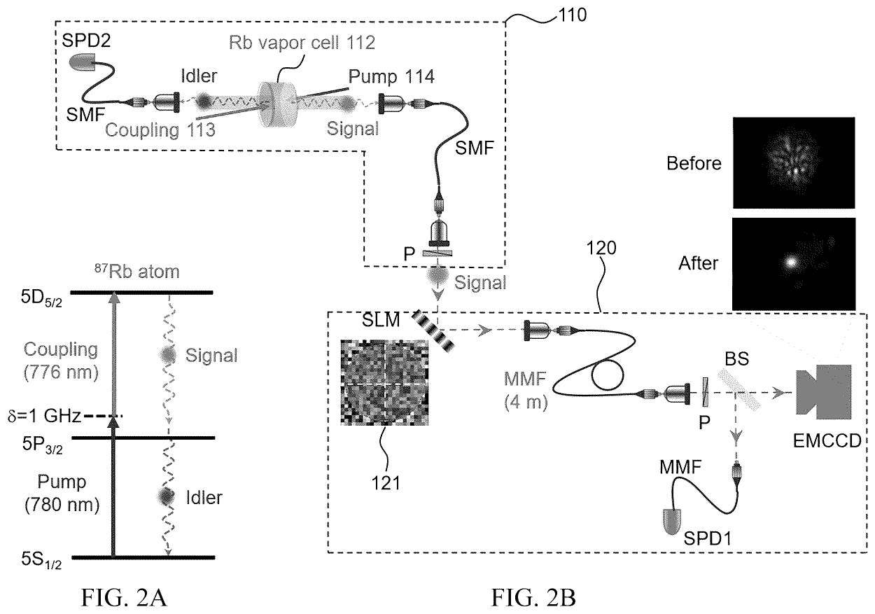

FIG. 2A is a diagram illustrating an energy level diagram of 5S_{1/2}-5P_{3/2}-5D_{5/2} transition of an ⁸⁷Rb atom according to one embodiment of the present disclosure.

Referring to FIG. 2A, an energy level diagram of 5S_{1/2}-5P_{3/2}-5D_{5/2} transition of an ⁸⁷Rb atom and a spontaneous four-wave mixing (SFWM) process may be shown in a cascade type atomic medium that constantly interacts with a pump and coupling lasers.

As shown in FIG. 2A, a photon pair may be directly generated in a warm atom ensemble and a strong correlation signal, and an idler photon may be emitted by a two-photon interference atom ensemble through an SFWM process.

A signal photon and an idler photon through the SFWM process may be generated in a phase coincidence condition corresponding to energy and momentum conservation. A phase coincidence function Φ(θ) as a function of a tilt angle θ of an idler signal and a signal with respect to a propagation direction of the pump laser 114 and the coupling laser 113 may be expressed by the following Equation 1.

$$ϕ ( θ ) = sin c ( \frac{Δ k ( θ ) L}{2} ) \qquad [ Equation 1 ]$$

In this case, Dk may denote wave-vector mismatch of four fields, that is, k_{p,c,i,s} may respectively denote wave vectors of pump, coupling field, idler, and signal photons, and L may denote the length of an ⁸⁷Rb vapor cell.

Frequencies of the emitted signal photon and the idler photon may satisfy an energy conservation relationship ωₚ+ω_{c}=ωₛ+ωᵢ, where ωₛ and ωᵢ may respectively denote frequencies of the signal photon and the idler photon.

A spatial mode of a signal photon and an idler photon collected by two single-mode optical fibers may be well superimposed and the spatial coherence of a backpropagation photon pair may be excellent due to a spatial mode filtering effect.

A diagram illustrates an example of implementing a multidimensional quantum state of a heralded single photon generated by an atom.

In FIG. 2B, an idler photon may be a trigger photon in a single-photon detector SPD2. Single coefficient velocities of a signal photon and an idler photon may be measured as 250(2) kHz and 196 kHz, respectively, with respect to an experimental parameter of a 20 mW pump and a 0.3 mW coupling laser. A photon pair coincidence count velocity may be measured as 3.8(1) kHz in a 3.5 ns coincidence window. As shown in FIG. 2B, to demonstrate a photon quark, a signal photon may be set to form a wavefront using the SLM 121 and a multimode fiber (MMF). In this case, a signal photon of a single-mode fiber (SMF) may be spatially filtered and may be propagated to the center of the SLM 121. In the SLM 121, a spatial mode of the signal photon may be TEM00 (a red circle shown in the SLM 121) and may be divided and programmed as a four-dimensional quantum state (a white dashed line). A phase of each section may be arbitrarily controlled by space division multiplexing of the SLM 121 and arbitrary superimposition of multiple states may be easily controlled.

The MMF may function as an arbitrary mode mixing circuit by combining phase patterns of wavefront formation optimization for each mode. The signal photon reflected by the SLM 121 may be launched as a grade index MMF having a core diameter of 62.5 m, a numerical aperture of 0.27, and a length of 4 m. Based on the assumption that the MMF is a step-index MMF, a lateral space and a polarization mode may be estimated to be up to 1200 at 780 nm.

In the MMF, there is a maximum path length difference between a short path and a long path. While the signal photon is propagated through the MMF with an arbitrary phase and amplitude, a spatial mode may be mixed and a spot pattern may be observed in an output. A photon emitted by the MMF may be split using a beam splitter (BS). An output plane of the MMF may be imaged by an electron-multiplying charged coupled device (EMCCD) and may monitor a wavefront formation process. In the settings of FIG. 2B, an input mode may be controlled by up to 900 segments of the SLM corresponding to 30′30 SLM macropixels.

An optical pattern of the SLM 121 may be shown because the optical pattern corresponds to a range of 0 (white) to 2p (black). In this case, maximum constructive interference may occur at one point by repeating an optimal phase for a segment of the SLM 121 and optimizing an output mode. In FIG. 2B, an output planar image of the EMCCD may be observed before and after iterative optimization of SLM 121. In the another path of the BS, quantum interference in an arbitrary four-dimensional quantum state may be measured using an SPD1. A core diameter of 62.5 mm connected to the SPD1 may be directly connected to the MMF.

A spatial mode filtering may not be required for interference pattern observation. This is because an output mode may be optimized at one point by repeating an optimal phase for each of the 900 SLM segments. An optimal wavefront for focusing may include a mode mixing process of various optical channels in the MMF and a scattering medium.

Accordingly, each state of space division multiplexing of a single photon may not be distinguished in a focus image after iterative optimization. However, a position of the MMF may need to be adjusted by considering an image plane of the EMCCD.

To implement quantum interference of spatial division multiplexing a single photon quark, a spatial single mode may be combined with the SLM 121 and the MMF through wavefront optimization. The present disclosure may use a stepwise sequential algorithm for an optimal wavefront for focusing. In the present disclosure, the algorithm may be implemented in the MMF using a phase pattern shown in the SLM and an image of the EMCCD. A typical iteration count may be up to 500 and an iteration time may be up to 40 minutes. In this case, the present disclosure may note that the brightness of a photon source and long coherence directly allow the implementation of a wavefront optimization technique. A phase pattern shown in the SLM may be optimized to focus on a single point.

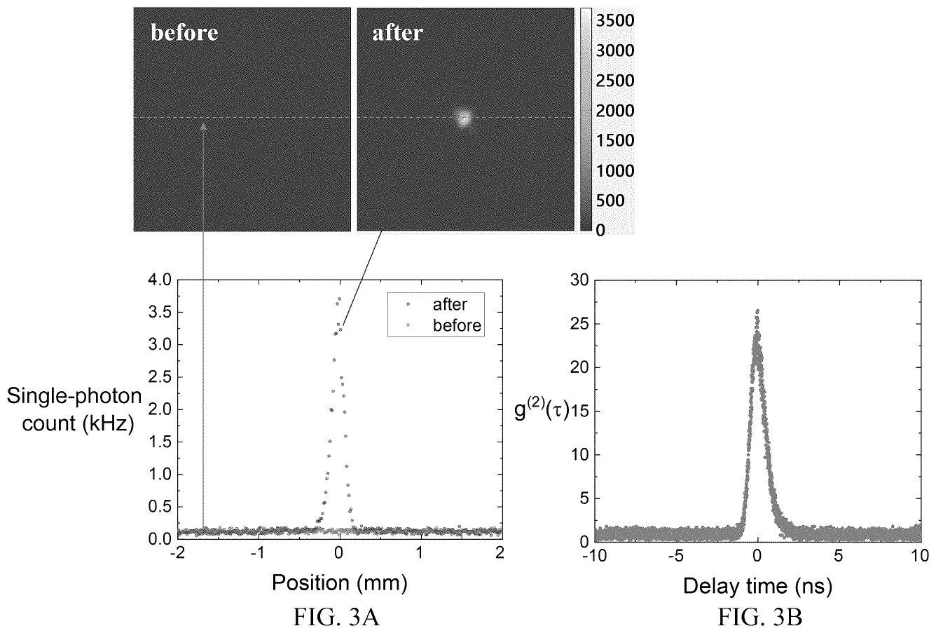

FIG. 3A is a diagram illustrating an output planar image obtained by an electron-multiplying charged coupled device (EMCCD) camera before and after optimization of the spatial light modulator (SLM) of FIG. 2B.

Referring to FIG. 3A, single photon velocity (a circle) after iterative optimization may be improved more than 30 times compared to an average single photon velocity (a rectangle) before optimization wherein a constant phase pattern is shown in the SLM 121.

A focusing signal photon may be measured as the focusing signal photon coincides with a trigger idler photon using a time-correlated single-photon counter (TCSPC) in a start-stop mode with 4 ps time resolution and a 3.5 ns coincidence window.

FIG. 3B is a diagram illustrating a normalized cross-correlation function between a signal photon detected by SPD1 of FIG. 2B and an idler photon detected by SPD2 (a trigger detector) of FIG. 2B.

Referring to FIG. 3B, an x-axis may represent a time delay from a signal to an idler photon.

In the present disclosure, it may be confirmed that a normalized cross-correlation function gₛᵢ⁽²⁾ represents a full width at half maximum (FWHM) up to 1.7 ns corresponding to Doppler broadening of an ⁸⁷Rb atom that is warm at 56° C.

In this case, a maximum value of the normalized cross-correlation function gₛᵢ⁽²⁾ may be measured as 27 during three minutes of an acquisition time and this may clearly represent a temporal correlation between an emitted signal and an idler photon through the SFWM process.

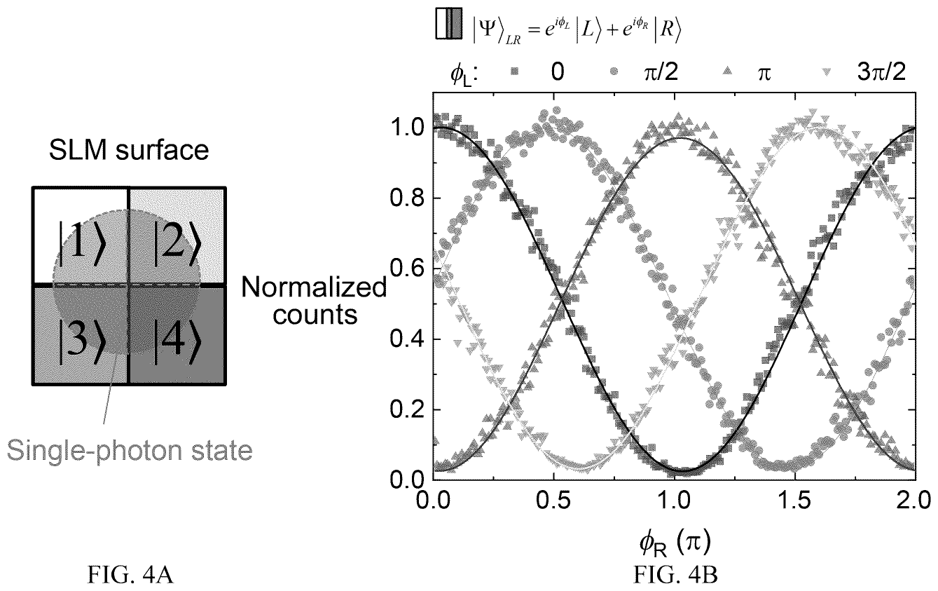

FIG. 4A is a diagram illustrating an example of dividing the surface of an SLM of a multidimensional quantum state generation apparatus into four segments according to one embodiment of the present disclosure.

Referring to FIG. 4A, a multidimensional quantum state generation apparatus may divide a surface of an SLM into four segments |1 [symbol] , |2 [symbol] , |3 [symbol] , and |4 [symbol] for space division multiplexing of a single photon (a red circle) and may deterministically manipulate a phase of each segment. Space division multiplexing may provide an advantage in that arbitrary superposition in a multiplexing state may be relatively easily controlled. In this case, a d-dimensional pure state may be d′1 column vector in a d-dimensional Hilbert space.

In FIG. 4A, four segments (d=4) of the SLM may be expressed by a single photon four-dimensional quantum state as Equation 2 shown below.

$$\vert Ψ 〉 = {A}_{1} {e}^{i {φ}_{1}} \vert 1 〉 + {A}_{2} {e}^{i {φ}_{2}} \vert 2 〉 + {A}_{3} {e}^{i {φ}_{3}} \vert 3 〉 + {A}_{4} {e}^{i {φ}_{4}} \vert 4 〉 \qquad [ Equation 2 ]$$

In this case, Aₙ may denote an amplitude, φₙ may denote a relative phase in a |n [symbol] state with respect to a reference phase and an optimization phase of the SLM to focus on a single point.

The four-dimensional space quantum state may be interfered with the MMF and |Ψ [symbol] state may be arbitrarily described by φₙ control.

FIG. 4B is a diagram illustrating a normalized number of a single photon when a relative phase (φ_{L}=0, p/2, p, 3p/2) of (PR changes to 234 stages from 0 to 2p in the multidimensional quantum state generation apparatus according to one embodiment of the present disclosure.

Referring to FIG. 4B, when relative phases of two segments of the surface of the SLM undergo the same change into 234 stages from 0 to 2p, in the case of horizontal space division as shown in FIG. 4B, a quantum interference pattern of a space qubit may be obtained. In this case, all amplitudes may be the same.

A fringe may be programmed as |Ψ [symbol] _{LR}=e^{iφ}^{_{L}}|L [symbol] +e^{iφ}^{_{R}}|R [symbol] to superimpose an input state. In this case, |L [symbol] =|1 [symbol] +|3 [symbol] and |R [symbol] =|2 [symbol] +|4 [symbol] . As a function of φ_{R}, it may be observed that an interference pattern of a single photon qubit may have visibility that is greater than or equal to 95% in four cases of φ_{L}. In this case, the visibility may be defined as V=(Nminₘₐₓ/(Nminₘₐₓ)), and Nₘₐₓ and Nₘᵢₙ may respectively denote maximum and minimum coefficient rates of a heralded single photon.

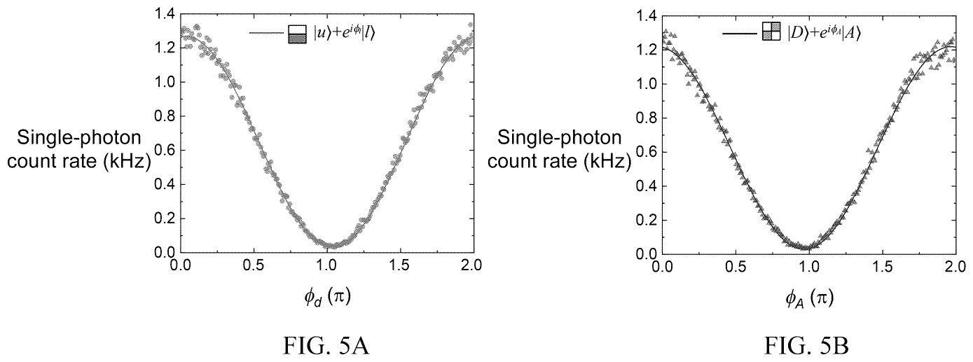

Next, two different cases of implementing a space qubit may be considered as FIG. 5.

FIG. 5A is a diagram illustrating quantum interference of a single photon qubit when the surface of an SLM is divided into top and bottom according to one embodiment of the present disclosure.

Referring to FIG. 5A, a red curve shows a case of superimposition between upper and lower segments |u [symbol] +e^{iφ}^{ₗ}|l [symbol] . In this case, |u [symbol] =|1 [symbol] +|2 [symbol] and |l [symbol] =|3 [symbol] +|4 [symbol] .

FIG. 5B is a diagram illustrating quantum interference of a single photon qubit when the surface of an SLM is diagonally divided according to one embodiment of the present disclosure.

Referring to FIG. 5B, a blue curve shows a case of superimposition between diagonal and anti-diagonal segments |D [symbol] +e^{iφ}^{_{A}}|A [symbol] . In this case, |D [symbol] =|1 [symbol] +|4 [symbol] and |A [symbol] =|2 [symbol] +|3 [symbol] .

Referring to FIGS. 5A and 5B, interference patterns of single photon qubits with visibility of 95.5(5)% and 95.3(5)% may be clearly observed in the case of perpendicular and diagonal lines, respectively. An error value of each visibility may be estimated by a standard deviation of a fitting curve.

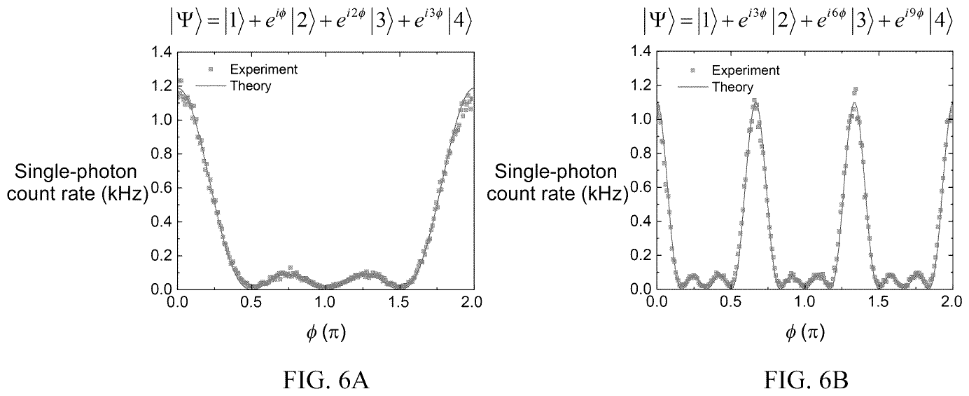

Next, interferences of four-dimensional space quantum states in the case of φ₁=0, φ₂φ, φ₃=2φ, φ₄=3φ and in the case of φ₁=0, φ₂=3φ, φ₃=6φ, φ₄=9φ are described with reference to FIGS. 6A and 6B, respectively.

FIG. 6A is a diagram illustrating an example of measuring interference in a four-dimensional (4D) space quantum state in the case of φ₁=0, φ₂=4, φ₃=2φ, φ₄=3φ in a multidimensional quantum state generation apparatus according to one embodiment of the present disclosure.

FIG. 6B is a diagram illustrating an example of measuring interference in a four-dimensional (4D) space quantum state in the case of φ₁=0, φ₂=3φ, φ₃=6φ, φ₄=9φ in a multidimensional quantum state generation apparatus according to one embodiment of the present disclosure.

The interferences measured in FIGS. 6A and 6B may correspond to an interference pattern from four slits. To obtain interference with high visibility, all amplitudes of segments by space division multiplexing of an SLM may be the same. In addition, when optimizing, a polarization mixing effect may be minimized using a polarizing plate as a polarizing filter. The interference visibility may be estimated as up to 95.4(5)%.

In FIG. 3B, by considering a cross-correlation function of a photon pair, the measure interference visibility may be restricted to the accidental number of photon pairs generated by warm Rb atomic ensemble. In addition, since a phase of each section may be arbitrarily controlled by space division multiplexing of the SLM, an arbitrary superimposition of photon qubits (d=3, 5, 6, . . . , 100) may be easily controlled.

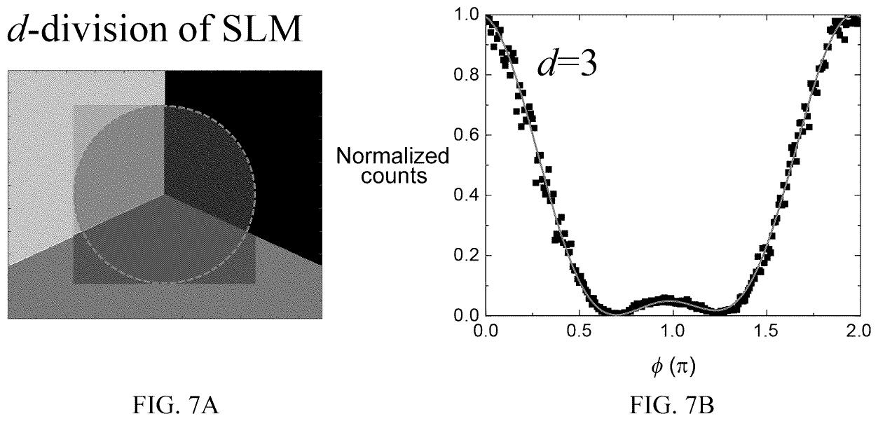

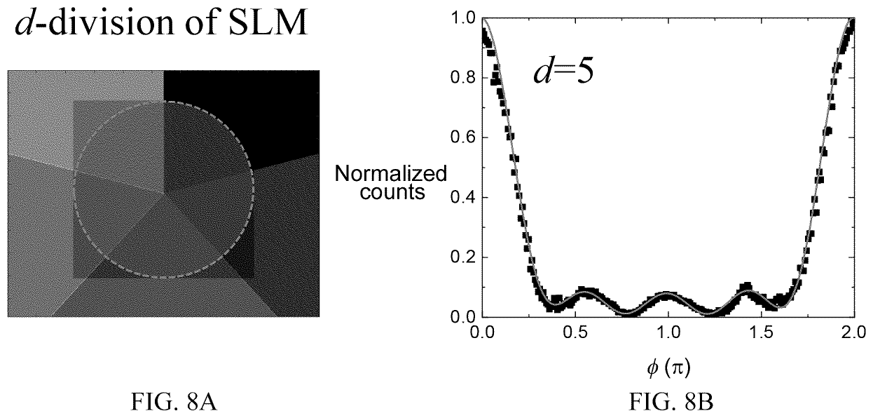

In addition, other than dividing segments of the SLM into two or four, examples of dividing segments of the SLM into three and five may be respectively shown in FIGS. 7A to 8B.

FIG. 7A is a diagram illustrating an example of dividing the surface of an SLM of a multidimensional quantum state generation apparatus into three segments according to one embodiment of the present disclosure.

FIG. 7B is a diagram illustrating an example of measuring interference of a 3D space quantum state when the surface of an SLM of a multidimensional quantum state generation apparatus is divided into three segments according to one embodiment of the present disclosure.

FIG. 8A is a diagram illustrating an example of dividing the surface of an SLM of a multidimensional quantum state generation apparatus into five segments according to one embodiment of the present disclosure.

FIG. 8B is a diagram illustrating an example of measuring interference of a 3D space quantum state when the surface of an SLM of a multidimensional quantum state generation apparatus is divided into five segments according to one embodiment of the present disclosure.

The number of radio wave modes of an MMF may be restricted by the number of maximum space modes. When the SLM provides complete control of all k radio wave modes of the MMF, a k=m input physical mode of the MMF may be controlled and injected. In this case, for each m input port, the number of adjustable elements of settings may be k. However, indeed, all radio wave modes of the MMF may not be completely used for the implementation of a high-dimensional quantum state. In the present disclosure, the number of space modes may be restricted to approximately 200 corresponding to an optical pattern stage of the SLM from 0 to 2p.

On the other hand, the multidimensional quantum state generation apparatus may perform amplitude modulation as well as phase modulation.

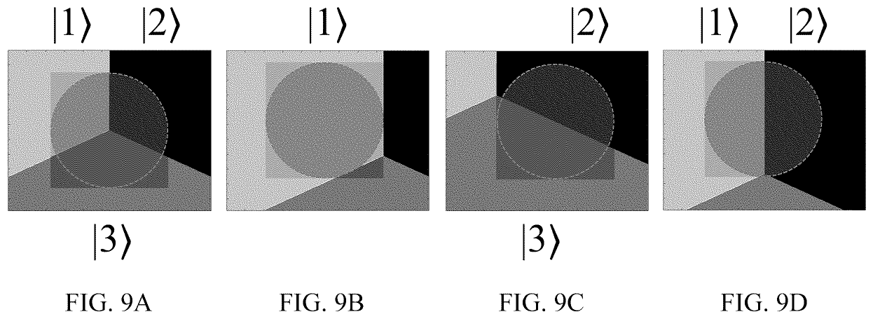

FIGS. 9A, 9B, 9C and 9D are drawings illustrating an example of dividing one state of a single photon into three quantum states by adjusting a ratio of three segments through amplitude modulation in an SLM of a multidimensional quantum state generation apparatus according to one embodiment of the present disclosure.

FIG. 9A illustrates an example of dividing one state of a single photon into three quantum states |1 [symbol] , |2 [symbol] , |3 [symbol] by dividing three segments of an SLM by the same ratio.

FIG. 9B is a diagram illustrating an example of making one state of a single photon one quantum state |1 [symbol] by dividing three segments of the SLM mainly based on a first segment.

FIG. 9C is a diagram illustrating an example of dividing one state of a single photon into two diagonally divided quantum states |2 [symbol] , |3 [symbol] by dividing three segments of the SLM mainly based on second and third segments.

FIG. 9D is a diagram illustrating an example of dividing one state of a single photon into two laterally divided quantum states |1 [symbol] , |2 [symbol] by dividing three segments of the SLM mainly based on the first and second segments.

Hereinafter, a method according to the present disclosure configured as described above will be described with reference to the drawings.

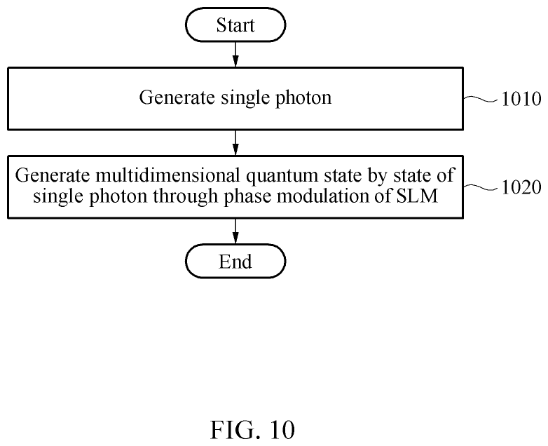

FIG. 10 is a flowchart illustrating a process of generating a multidimensional quantum state according to one embodiment of the present disclosure.

Referring to FIG. 10, in operation 1010, the multidimensional quantum state generation apparatus 100 may generate a single photon.

In this case, operation 1010 may provide an atomic vapor cell containing a rubidium (⁸⁷Rb) atom, may move a coupling laser and a pump laser in opposite directions to each other, may generate a photon pair of a signal and an idler from the atomic vapor cell, and may output a signal photon as a single photon.

In addition, when providing the atomic vapor cell, the multidimensional quantum state generation apparatus 100 may provide a glass-type cell that maintains the gas of a warm rubidium (⁸⁷Rb) atom.

In addition, in operation 1020, the multidimensional quantum state generation apparatus 100 may generate a multidimensional quantum state by space division multiplexing a state of the single photon through phase modulation of an SLM.

In operation 1020, the multidimensional quantum state generation apparatus 100 may generate a two-dimensional quantum state by space division multiplexing a single photon state into left and right sides through phase modulation of the SLM.

In operation 1020, the multidimensional quantum state generation apparatus 100 may generate a two-dimensional quantum state by space division multiplexing a single photon state into top and bottom sides through phase modulation of the SLM.

In operation 1020, the multidimensional quantum state generation apparatus 100 may generate a 4D quantum state by space division multiplexing a single photon state into quadrants of top, bottom, left, and right sides through phase modulation of the SLM.

In operation 1020, the multidimensional quantum state generation apparatus 100 may generate a two-dimensional quantum state by space division multiplexing by dividing a single photon state into top, bottom, left, and right quadrants through phase modulation of the SLM, allocating the same phase to top-left and bottom-right of the divided quadrants, and allocating the same phase to top-right and bottom-left of the divided quadrants.

The methods according to the above-described examples may be recorded in non-transitory computer-readable media including program instructions to implement various operations of the above-described examples. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape, optical media such as CD-ROM discs, DVDs, and/or Blue-ray discs, magneto-optical media such as optical discs, and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher-level code that may be executed by the computer using an interpreter. The above-described devices may be configured to act as one or more software modules in order to perform the operations of the above-described example embodiments, or vice versa.

The software may include a computer program, a piece of code, an instruction, or some combination thereof, to independently or uniformly instruct or configure the processing device to operate as desired. Software and data may be embodied permanently or temporarily in any type of machine, component, physical or pseudo equipment, computer storage medium or device, or in a propagated signal wave capable of providing instructions or data to or being interpreted by the processing device. The software also may be distributed over network-coupled computer systems so that the software is stored and executed in a distributed fashion. The software and data may be stored by one or more non-transitory computer-readable recording mediums.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents.

Accordingly, other implementations are within the scope of the following claims.

What is claimed is:

1. A multidimensional quantum state generation apparatus comprising:
a photon generator configured to generate a single photon; and
a multidimensional quantum state generator configured to generate a multidimensional quantum state by space division multiplexing a state of the single photon through phase modulation of a spatial light modulator (SLM).

2. The multidimensional quantum state generation apparatus of claim 1, wherein the single photon comprises a heralded single photon.

3. The electronic device of claim 1, wherein the multidimensional quantum state generator is configured to generate a two-dimensional quantum state by space dividing multiplexing the state of the single photon into a left side and a right side through phase modulation of the SLM.

4. The multidimensional quantum state generation apparatus of claim 1, wherein the multidimensional quantum state generator is configured to generate a two-dimensional quantum state by space dividing multiplexing the state of the single photon into a top side and a bottom side through phase modulation of the SLM.

5. The multidimensional quantum state generation apparatus of claim 1, wherein the multidimensional quantum state generator is configured to generate a four-dimensional quantum state by space dividing multiplexing the state of the single photon into top, bottom, left, and right quadrants through phase modulation of the SLM.

6. The multidimensional quantum state generation apparatus of claim 1, wherein the multidimensional quantum state generator is configured to generate a two-dimensional quantum state by space division multiplexing by dividing the state of the single photon into top, bottom, left, and right quadrants through phase modulation of the SLM, allocate a same phase to top-left and bottom-right of the divided quadrants, and allocate a same phase to top-right and bottom-left of the divided quadrants.

7. The multidimensional quantum state generation apparatus of claim 1, wherein the multidimensional quantum state is dividable into multidimensions up to a range supported by a resolution of the SLM.

8. The multidimensional quantum state generation apparatus of claim 1, wherein the photon generator comprises:
an atomic vapor cell containing a rubidium (87Rb) atom; and
a processor configured to move a coupling laser and a pump laser in opposite directions to each other relative to the atomic vapor cell, generate a pair of signal and idler photons in the atomic vapor cell, and output a signal photon as the single photon.

9. The multidimensional quantum state generation apparatus of claim 8, wherein the coupling laser comprises a 776 nm laser of horizontal polarization,
the pump laser comprises a 780 nm laser of vertical polarization, and
the coupling laser and the pump laser simultaneously move toward the atomic vapor cell in opposite directions to each other from respective positions spaced apart from the atomic vapor cell by a same distance.

10. The multidimensional quantum state generation apparatus of claim 8, wherein the processor is configured to generate the photon pair of which the signal and the idler are in a perpendicular polarization relationship that is horizontal polarization and vertical polarization or vertical polarization and horizontal polarization by the coupling laser of horizontal polarization and the pump laser of vertical polarization.

11. The multidimensional quantum state generation apparatus of claim 8, wherein the coupling laser and the pump laser fix a laser frequency at +1 GHz outside a Doppler broadening region to reduce an irrelevant photon pair generated by photon resonance.

12. The multidimensional quantum state generation apparatus of claim 8, wherein the atomic vapor cell comprises a glass-type cell that maintains gas of the rubidium (87Rb) atom warm.

13. A method of generating a multidimensional quantum state, the method comprising:
generating a single photon; and
generating a multidimensional quantum state by space division multiplexing a state of the single photon through phase modulation of a spatial light modulator (SLM).

14. The method of claim 13, wherein the generating of the multidimensional quantum state comprises generating a two-dimensional quantum state by space dividing multiplexing the state of the single photon into a left side and a right side through phase modulation of the SLM.

15. The method of claim 13, wherein the generating of the multidimensional quantum state comprises generating a two-dimensional quantum state by space dividing multiplexing the state of the single photon into a top side and a bottom side through phase modulation of the SLM.

16. The method of claim 13, wherein the generating of the multidimensional quantum state comprises generating a four-dimensional quantum state by space dividing multiplexing the state of the single photon into top, bottom, left, and right quadrants through phase modulation of the SLM.

17. The method of claim 13, wherein the generating of the multidimensional quantum state comprises generating a two-dimensional quantum state by space division multiplexing by dividing the state of the single photon into top, bottom, left, and right quadrants through phase modulation of the SLM, allocating a same phase to top-left and bottom-right of the divided quadrants, and allocating a same phase to top-right and bottom-left of the divided quadrants.

18. The method of claim 13, wherein the generating of the single photon comprises:
providing an atomic vapor cell containing a rubidium (87Rb) atom; and
moving a coupling laser and a pump laser in opposite directions to each other relative to the atomic vapor cell, generating a pair of signal and idler photons in the atomic vapor cell, and outputting a signal photon as the single photon.

19. The method of claim 18, wherein the providing of the atomic vapor cell comprises providing a glass-type cell that maintains gas of the rubidium (87Rb) atom warm.

20. A non-transitory computer-readable storage medium storing instructions that, when executed by a processor, cause the processor to perform the method of claim 13.
